(19) United States
(12) Patent Application Publication
(10) Pub. No.: US 2014/0354358 A1
(43) Pub. Date: Dec. 4, 2014

(54) POWER AMPLIFIER

(71) Applicant: Postech Academy-Industry Foundation, Pohang-si (KR)

(72) Inventors: Bum Man Kim, Daejam Central Heights (KR); Sang su Jin, Ocean city (KR)

(73) Assignee: Postech Academy-Industry Foundation, Pohang-si (KR)

(21) Appl. No.: 14/288,461

(22) Filed: May 28, 2014

(30) Foreign Application Priority Data
May 31, 2013 (KR) 10-2013-0062430

(51) Int. Cl. H03F 3/21; H03F 3/45

(52) U.S. Cl. CPC H03F 3/211; H03F 3/45179; H03F 2200/387; H03F 2203/45576; H03F 2203/21148
USPC 330/253; 330/261

(57) ABSTRACT

The present disclosure relates to a power amplifier, the power amplifier including a first amplifier configured to form a common source by allowing sources of a plurality of first transistors to be commonly connected, a second amplifier configured to form a common source by allowing sources of a plurality of second transistors to be commonly connected and to be respectively connected in a cascode structure to the plurality of first transistors of the first amplifier, and a controller configured to be connected to a common gate node to short-circuit second harmonic impedance of the common gate.

Pursuant to 35 U.S.C.§119 (a), this application claims the benefit of earlier filing date and right of priority to Korean Patent Application No.10-2013-0062430, filed on May 31, 2013, the contents of which are hereby incorporated by reference in their entirety.

### BACKGROUND OF THE DISCLOSURE

1. Technical Field

The teachings in accordance with the exemplary embodiments of this present disclosure generally relate to a power amplifier.

2. Background

Many demands are required in recent years to integrate wireless transceiver into a single chip, and researches into the integration of wireless transceiver in a single chip have been actively conducted. One of the greatest reasons that requires the demand is that only a power amplifier is implemented by using an indium gallium phosphide (InGaP)/gallium arsenide (GaAs) heterojunction bipolar transistor (HBT) process, among the blocks of the wireless transceiver,

Compared with the CMOS (Complementary Metal Oxide Semiconductor) process, the InGaP/GaAs HBT process suffers disadvantages in that it incurs high manufacturing costs, requires a multi-chip structure, and has difficulty in being coupled to a control circuit block implemented according to the CMOS process to improve linearity. For these reasons, researches into a power amplifier based on the CMOS process have been actively implemented because a wireless transceiver can be manufactured in a single chip.

In case of employing a power amplifier based on the CMOS process in order to cope with the abovementioned problems, a power amplifier is employed that has a cascode structure in which a plurality of transistors are stacked due to low breakdown voltage characteristics of a CMOS element compared with the case in which the foregoing HBT process is employed.

The most fundamental cascode amplifier structure is configured by using a common source amplifier in a first layer positioned at an input terminal and a common gate amplifier in a second layer positioned at an output terminal, by which manner common gate amplifiers may be added to third and fourth layers to thereby enhance a breakdown voltage characteristic. An external power is supplied to the power amplifier for amplifying operation.

Generally, a common gate node of differential structure is formed with a virtual ground at the common gate node due to differential operation, and provides a ground to an odd harmonic component. A node of the cascode amplifier is applied with an external power using the common gate node. The external power is supplied to a gate of common source, a gate of common gate and a drain of a common gate in case of 2-stage cascode amplifier structure.

FIG. 1 is a schematic view illustrating a structure of a power amplifier (100) using a CMOS device according to prior art.

Referring to FIG. 1, a common source amplifier (110) at an input terminal functions as a main amplification section, while a common gate amplifier (120) used to reduce a breakdown voltage functions two roles in this structure. A first role is to function as a current buffer amplifier, and second role is to be recognized as a drain of common source amplifier as a serial on-resistor. That is, the common gate amplifier (110) is equivalently an output load of the common gate amplifier (110). The most important part in designing a power amplifier is an output load. It is because an entire efficiency and characteristics are changed by envelope curve, first, second and third impedances of the output load.

The conventional power amplifier (100) is a gate bias circuit (130) of common gate amplifier (120), and employs a resistor and an inductor to reduce an RF noise supplied from outside and to supply a clean DC electric power. However, this method suffers, because of the following reasons, from drawbacks that fail to provide an AC ground to a gate of the common gate amplifier (120) relative to all harmonic impedances:

First, a common node cannot provide a ground to even harmonics. Second, the common source amplifier (110) and the common gate amplifier (120) of the cascode power amplifier are asymmetrical in each unit CMOS transistor that forms the amplifier. Third, a secondary asymmetrical component may be generated by asymmetrical capacitors (C ds, C gs) generated when a voltage between source and drain of the CMOS transistor and a voltage between source and gate are changed.

The impedance corresponding to a tone-spacing frequency of low harmonics in the even harmonics in the common node, i.e., envelope or two-tone signal may be real-valued by sufficiently short-circuiting a reactance using a bias circuit of adequate value. However, it is difficult to short-circuit using the existing bias alone, because secondary harmonic impedance in the even harmonic components corresponds to a harmonic component (twice the fundamental frequency). Because of this reason, unless the secondary harmonic nonlinearity characteristic is removed from a gate of the common gate amplifier (120), the linearity characteristic can be degraded by the memory effect and even nonlinearity characteristic to reduce a final linear output power, whereby entire efficiency can be deteriorated.

Meantime, in the course of solving the aforesaid drawbacks, another problem arises that requires an external circuit such as a linear pre-distortion or ET (Envelope Tracking) must be employed to incur separate expenses.

### SUMMARY OF THE DISCLOSURE

The present disclosure is to provide a power amplifier configured to reduce memory effect by controlling secondary harmonic impedance in a gate of the common gate of cascode power amplifier, and to enhance efficiency and linearity in an entire region of output power of the power amplifier.

In one general aspect of the present disclosure, there is provided a power amplifier, comprising: a first amplifier configured to form a common source by allowing sources of a plurality of first transistors to be commonly connected; a second amplifier configured to form a common source by allowing sources of a plurality of second transistors to be commonly connected and to be respectively connected in a cascode structure to the plurality of first transistors of the first amplifier; and a controller configured to be connected to a common gate node to short-circuit second harmonic impedance of the common gate.

In some exemplary embodiment of the present invention, the controller may include a bonding wire and a capacitor being connected in series.

In some exemplary embodiment of the present invention, the controller may include an inductor and a capacitor being connected in series.

In some exemplary embodiment of the present invention, the controller may include a bonding wire, an inductor and a capacitor being connected in series.

In some exemplary embodiment of the present invention, the first and second amplifiers may be arranged in differential cascode structure.

In some exemplary embodiment of the present invention, the first and second amplifiers may be arranged in single cascode structure.

In some exemplary embodiment of the present invention, the power amplifier may further comprise a balloon unit configured to convert a single signal to a balance signal and to provide the converted balance signal to the first amplifier.

In some exemplary embodiment of the present invention, the power amplifier may further comprise a matching unit configured to match impedance on a signal path between an output terminal of the second amplifier and an output terminal of the power amplifier.

In some exemplary embodiment of the present invention, the power amplifier may further comprise a bias supplier configured to supply an inputted bias voltage to a gate node of the second amplifier.

### ADVANTAGEOUS EFFECT OF THE DISCLOSURE

The power amplifier according to an exemplary embodiment of the present disclosure has an advantageous effect in that linearity can be enhanced by connecting a circuit configured to control second harmonic impedance to a common gate node, and short-circuiting or real-valuing the second harmonic impedance, the power amplifier can be simplified free from an additional outside element, and enhanced in efficiency over a conventional power amplifier.

### BRIEF DESCRIPTION OF DRAWINGS

FIG. 1 is a schematic view illustrating a circuit diagram of a power amplifier using a CMOS device according to prior art.

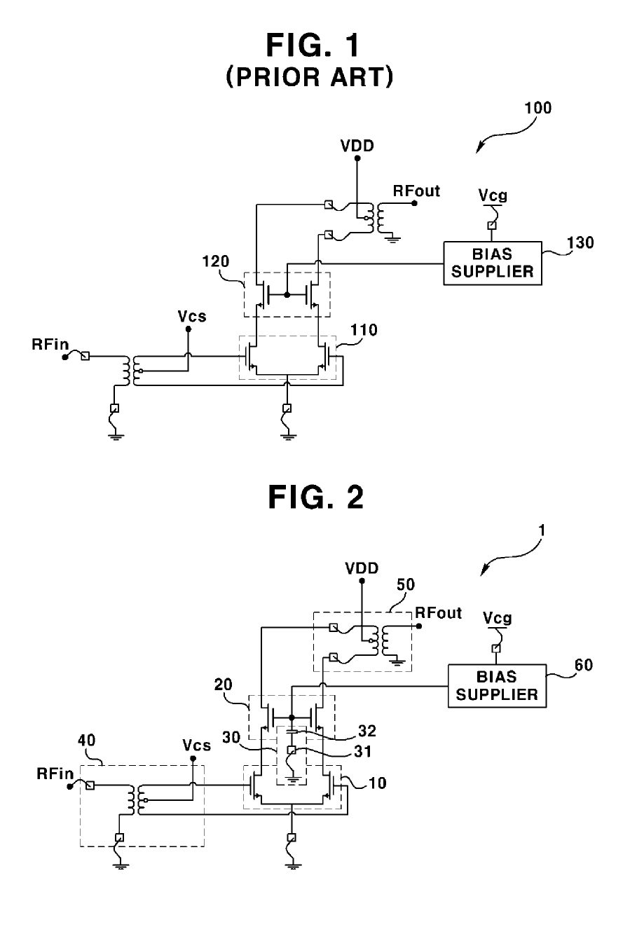

FIG. 2 is a schematic view illustrating a basic circuit diagram of a power amplifier according to an exemplary embodiment of the present disclosure.

FIG. 3 is an exemplary view of layout of a power amplifier according to an exemplary embodiment of the present disclosure.

FIGS. 4A-4B are, respectively, exemplary views illustrating a second harmonic impedance of a second amplifier based on change in input voltage, change in carrier frequency and position of unit transistor according to an exemplary embodiment of the present disclosure.

FIG. 5 is a comparative graph between IMD3 and PAE (Power Added Efficiency) according to an output voltage of a conventional power amplifier and an output voltage of a power amplifier according to an exemplary embodiment of the present disclosure.

### DETAILED DESCRIPTION OF THE DISCLOSURE

Various exemplary embodiments will be described more fully hereinafter with reference to the accompanying drawings, in which some exemplary embodiments are shown. The present inventive concept may, however, be embodied in many different forms and should not be construed as limited to the example embodiments set forth herein. Rather, the described aspect is intended to embrace all such alterations, modifications, and variations that fall within the scope and novel idea of the present disclosure.

The power amplifier in a cascode structure according to an exemplary embodiment of the present disclosure can remove non-linearity (called a memory effect) of an IMD (Inter Modulation Distortion) at an upper surface and a lower surface of the power amplifier by removing a second harmonic impedance through short-circuit of control of the second harmonic impedance of common gate or through impedance real value by removal of reactance, and can enhance the efficiency and linearity at an entire region of output power of the power amplifier by reducing the size of IMD itself.

Now, an exemplary embodiment of the present disclosure will be described in detail with reference to the accompanying drawings.

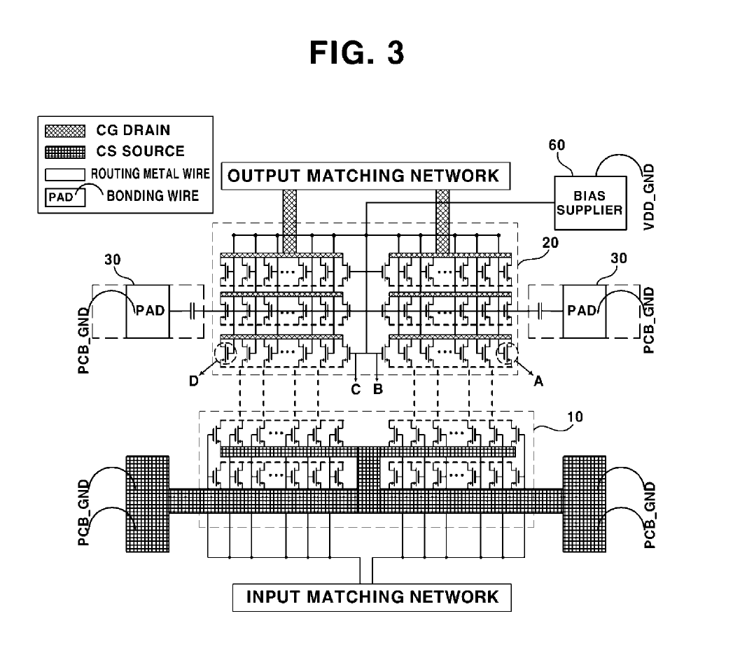

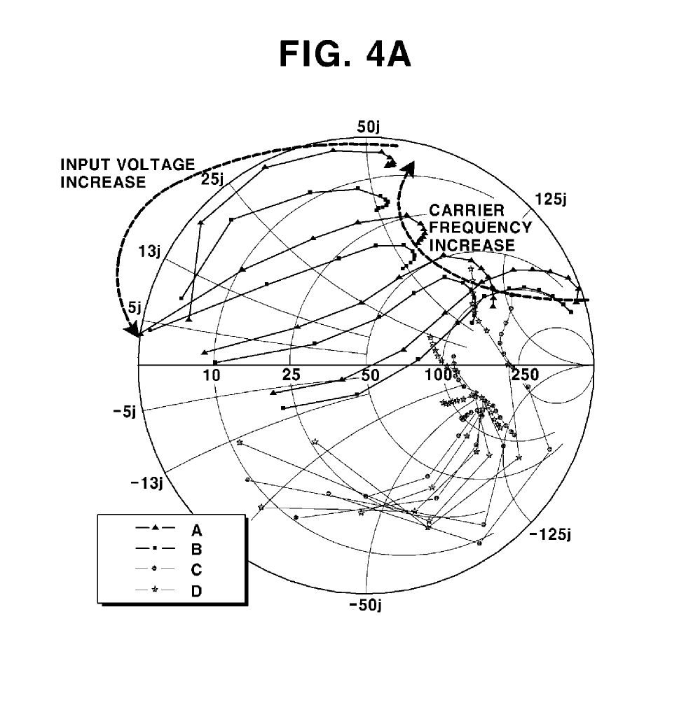

FIG. 2 is a schematic view illustrating a basic circuit diagram of a power amplifier (1) according to an exemplary embodiment of the present disclosure and FIG. 3 is an exemplary view of layout of a power amplifier according to an exemplary embodiment of the present disclosure.

Referring to FIG. 2, the power amplifier (1) according to the exemplary embodiment of the present disclosure may include a first amplifier (10), a second amplifier (20) configured to be connected to the first amplifier (10) in a cascode structure, and a second harmonic controller (30).

The power amplifier (1) according the exemplary embodiment of the present disclosure may further include a balloon unit (40), an impedance matching unit (50) and a bias supplier (60), in addition to the first amplifier (10), the second amplifier (20) and the second harmonic controller (30).

The first and second amplifiers (10, 20) of the power amplifier (1) according the exemplary embodiment of the present disclosure may be embodied by CMOS process.

The first and second amplifiers (10, 20) are connected in a cascode structure, where the cascode structure means that a transistor device of the first amplifier (10) and a transistor device of the second amplifier (20) are respectively connected in series. Although the exemplary embodiment of the present disclosure has explained and described a configuration where the first and second amplifiers (10, 20) are serially connected by two transistors in a cascode structure, the present disclosure is not limited thereto, the number of amplifiers is not limited and two or more plural number of transistors may be connected to form a common node.

FIG. 3 is an exemplary view of layout of a power amplifier in which first and second amplifiers (10, 20) have a plurality of transistors.

Furthermore, although the power amplifier (1) of the present disclosure has illustrated a two-stage cascode structure of the first amplifier (10) and the second amplifier (20, the present disclosure is not limited thereto, and a multi-stage cascode structure may be formed. That is, the present disclosure may be configured in such a manner that the first amplifier (10) is configured in a multi-stage cascode structure and the second amplifier (20) may be configured in a common gate node.

The first amplifier (10) operates as a main amplifier, where a plurality of transistors may be connected in parallel, and sources of a plurality of transistors may be commonly connected to form a common source.

The second amplifier (20) performs an amplification operation to mitigate a breakdown voltage from the first amplifier (10), where a plurality of transistors may be connected in parallel to form a common gate by connecting a plurality of gates of the plurality of transistors.

Transistors of the first and second amplifiers (10, 20) may be MOSFETs (Metal-Oxide-Semiconductor Field-Effect Transistors), but the transistors of the first and second amplifiers (10, 20) are not limited thereto.

The signal amplification operation of first and second amplifiers (10, 20) is apparent to the skilled in the art and therefore no further descriptions will be made thereto.

Each of the first and second amplifiers (10, 20) may be formed with unit CMOS element, whereby another second harmonic impedance may be generated from each node of CMOS element. A second harmonic controller (30) is included in the exemplary embodiment of the present disclosure in order to control said another second harmonic impedance. The second harmonic controller (30) may be connected to the common gate of the second amplifier (20) in order to shirt-circuit or control the second harmonic impedance. The second harmonic controller (30) may include a boding wire (31) or a capacitor (32) as illustrated in FIG. 2.

The bonding wire (31) is a conductive wire employed to electrically connect terminals or circuits in the conventional semiconductor manufacturing, and may be modeled by an inductor on an equivalent value.

Although the second harmonic controller (30) according to the present disclosure is exemplified by a serial connection between the bonding wire (31) and the capacitor (32), the present disclosure is not limited thereto, and any configuration for controlling the harmonic impedance may be included. That is, the second harmonic controller (30) may be configured by serial connection between an inductor and a capacitor, or by serial connection of a boning wire, an inductor and a capacitor, for example.

The second harmonic controller (30) is configured such that the bonding wire or inductance of inductor and capacitance of capacitor are determined to remove the second harmonic impedance or to remove the reactance component of impedance by controlling the second harmonic of the second amplifier (20).

In general, an impedance include a resistance of real number component and a reactance of imaginary number component, and second harmonic controller (30) of the present disclosure is configured such that the reactance component is removed by the second harmonic impedance of common gate of the second amplifier (20) to render the impedance to be real-valued, or the reactance and resistance components are all removed to short-circuit the impedance.

Referring to FIG. 2 again, the balloon unit (40) may include a primary winding (P) and a secondary winding (S), whereby a single signal (RFin) is converted to a balance signal and provided to the first amplifier (10). The impedance matching unit (50) may match impedances on a signal path between an output terminal of the second amplifier (20) and an output terminal (RFout) of the power amplifier (1). Furthermore, the bias supplier (60) may supply an inputted bias voltage (Vcg) to a common gate node of the second amplifier (20).

Although FIG. 2 illustrates a power amplifier in a differential cascode structure according to an exemplary embodiment of the present disclosure, it should be noted that a single cascode structure of power amplifier is not ruled out from the exemplary embodiment of the present disclosure. That is, it would be apparent to the skilled in the art that the first and second amplifiers (10, 20) may be constituted in one transistor, where the second harmonic controller (30) may be connected to the gate of the second amplifier (20).

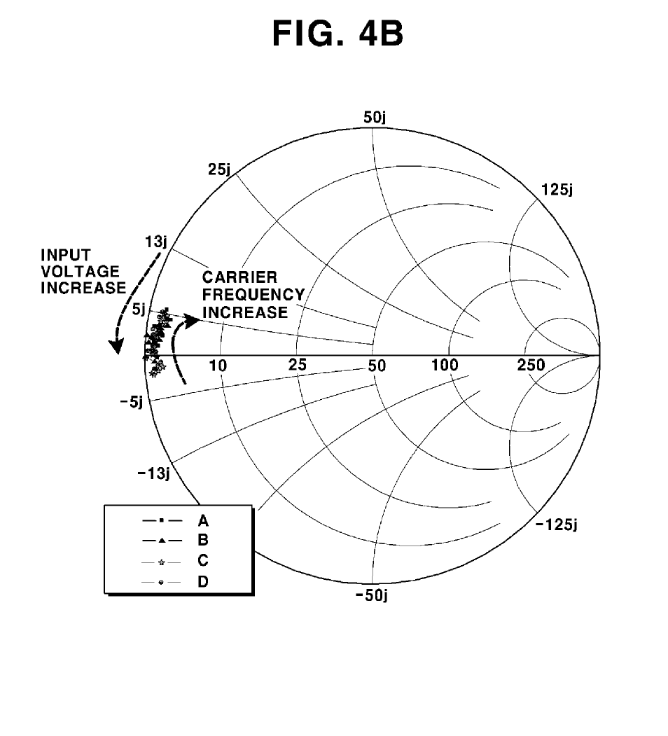

FIGS. 4A and 4B are exemplary views illustrating a second harmonic impedance of a second amplifier based on change in input voltage, change in carrier frequency and position of unit transistor according to an exemplary embodiment of the present disclosure, where FIG. 4A illustrates the second harmonic amplifier (30) not being applied to the layout of FIG. 3, and FIG. 4B illustrates the second harmonic amplifier (30) being applied to the layout of FIG. 3. Furthermore, A, B, C, D of FIGS. 4A and 4B illustrate positions of transistors A, B, C, and D to explain the second harmonic impedance of a relevant transistor.

Referring to FIG. 4A, it can be noted that, when the second harmonic controller (30) according to the present disclosure, second harmonic impedance has a different value according to carrier frequency used in response to input power and according to the position the unit CMOS element is located, and has a very large value. Thus, the linearity of the power amplifier (1) decreases by non-linear parasitic element to thereby reduce an entire efficiency and output power.

However, when the second harmonic controller (30) according to the present disclosure is applied, the second harmonic impedance components detected by the A,B,C,D elements can be all short-circuited or come to have low impedance as illustrated in FIG. 4B.

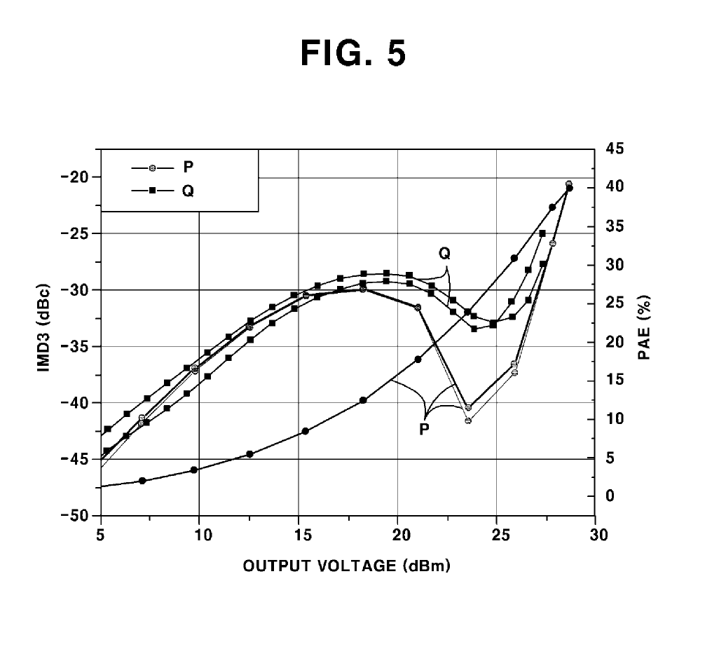

FIG. 5 is a comparative graph between IMD3 and PAE (power added efficiency) according to an output voltage of a conventional power amplifier and an output voltage of a power amplifier according to an exemplary embodiment of the present disclosure, where P illustrates IMD3 and PAE characteristics of the power amplifier (1) according to operation of the second harmonic controller (30) of the present disclosure, and Q illustrates IMD3 and PAE characteristics of the conventional power amplifier where the second harmonic controller (30) is not operated. At this time, the IMD3 shows a third-order intermodulation distortion and PAE shows power added efficiency.

As illustrated in FIG. 5, it can be noted from the power amplifier (1) according to an exemplary embodiment of the present disclosure that the second harmonic non-linear component is removed from the gate node of the common gate, and the non-linearity at the upper surface and lower surface of IMD3 (memory effect) is definitely removed to enhance the IMD3 and PAE.

Although the present disclosure has been described in detail with reference to the foregoing embodiments and advantages, many alternatives, modifications, and variations will be apparent to those skilled in the art within the metes and bounds of the claims. Therefore, it should be understood that the above-described embodiments are not limited by any of the details of the foregoing description, unless otherwise specified, but rather should be construed broadly within the scope as defined in the appended claims

What is claimed is:

1. A power amplifier, comprising:
a first amplifier configured to form a common source by allowing sources of a plurality of first transistors to be commonly connected;
a second amplifier configured to form a common source by allowing sources of a plurality of second transistors to be commonly connected and to be respectively connected in a cascode structure to the plurality of first transistors of the first amplifier; and
a controller configured to be connected to a common gate node to short-circuit second harmonic impedance of the common gate.

2. The power amplifier of claim 1, wherein the controller includes a bonding wire and a capacitor being connected in series.

3. The power amplifier of claim 1, wherein the controller includes an inductor and a capacitor being connected in series.

4. The power amplifier of claim 1, wherein the controller includes a bonding wire, an inductor and a capacitor being connected in series.

5. The power amplifier of claim 1, wherein the first and second amplifiers are arranged in differential cascode structure.

6. The power amplifier of claim 1, wherein the first and second amplifiers are arranged in single cascode structure.

7. The power amplifier of claim 1, further comprising:
a balloon unit configured to convert a single signal to a balance signal and to provide the converted balance signal to the first amplifier.

8. The power amplifier of claim 1, further comprising:
a matching unit configured to match impedance on a signal path between an output terminal of the second amplifier and an output terminal of the power amplifier.

9. The power amplifier of claim 1, further comprising:
a bias supplier configured to supply an inputted bias voltage to a gate node of the second amplifier.
